(19) United States
(12) Patent Application Publication
(10) Pub. No.: US 2016/0155848 A1
(43) Pub. Date: Jun. 2, 2016

(54) THIN FILM TRANSISTOR AND METHOD OF MANUFACTURING THE SAME, AND DISPLAY UNIT AND ELECTRONIC APPARATUS

(71) Applicant: Sony Corporation, Tokyo (JP)

(72) Inventors: Junji Iwasaki, Kanagawa (JP); Yasuhiro Terai, Kanagawa (JP)

(21) Appl. No.: 14/747,579

(22) Filed: Jun. 23, 2015

(30) Foreign Application Priority Data
Nov. 28, 2014 (JP) 2014-242366

(51) Int. Cl. H01L 29/786; H01L 29/66; H01L 29/45; H01L 29/423; H01L 29/24

(52) U.S. Cl. CPC H01L 29/7869; H01L 29/42356; H01L 29/78606; H01L 29/24; H01L 29/45; H01L 29/66969

(57) ABSTRACT

Provided is a thin film transistor, including: a gate electrode; a gate insulating film covering the gate electrode; an oxide semiconductor layer provided on the gate insulating film; a source electrode and a drain electrode provided in a spaced, side-by-side relationship, in which the source electrode and the drain electrode each are connected to the oxide semiconductor layer; a first protective film covering the source electrode and the drain electrode, filling a gap between the source electrode and the drain electrode, and configured of a material including a silicon (Si) compound; a second protective film covering the first protective film and configured of a material including a metal compound; and a metal layer covering a region, over the second protective film, superposed on the gap between the source electrode and the drain electrode.

### CROSS REFERENCE TO RELATED APPLICATIONS

This application claims the benefit of Japanese Priority Patent Application JP 2014-242366 filed on Nov. 28, 2014, the entire contents of which are incorporated herein by reference.

### BACKGROUND

The present disclosure relates to a thin film transistor (TFT) including an oxide semiconductor, and a display unit including the thin film transistor and an electronic apparatus.

Recently, research and development of oxide semiconductors such as, but not limited to, zinc oxide and indium gallium zinc oxide has become active with an aim to apply them to electronic devices such as thin film transistors, light emitting devices, and transparent conductive films. It has been found that these oxide semiconductors, when used as an active layer (a channel) of a TFT, exhibit high electron mobility and excellent electrical characteristics, as compared to a TFT using amorphous silicon. Moreover, oxide semiconductors also have other advantages that high mobility is expected even at a low temperature around room temperature. Thus, the development of the oxide semiconductors has been actively promoted. As such TFTs using such oxide semiconductors, bottom-gate and top-gate structures have been reported (for example, refer to International Publication No. WO2005-088726, and Japanese Unexamined Patent Application Publication Nos. 2007-194594 and 2014-60411).

### SUMMARY

However, thin film transistors including oxide semiconductors may vary in operation characteristics due to influences by a disturbance substance such as water or an electric field.

It is desirable to provide a thin film transistor that makes it possible to enhance operation reliability and a manufacturing method thereof, and a display unit including the thin film transistor and an electronic apparatus.

According to an embodiment of the present disclosure, there is provided a thin film transistor, including: a gate electrode; a gate insulating film covering the gate electrode; an oxide semiconductor layer provided on the gate insulating film; a source electrode and a drain electrode provided in a spaced, side-by-side relationship, in which the source electrode and the drain electrode each are connected to the oxide semiconductor layer; a first protective film covering the source electrode and the drain electrode, filling a gap between the source electrode and the drain electrode, and configured of a material including a silicon (Si) compound; a second protective film covering the first protective film and configured of a material including a metal compound; and a metal layer covering a region, over the second protective film, superposed on the gap between the source electrode and the drain electrode.

According to an embodiment of the present disclosure, there is provided a display unit provided with a thin film transistor and a display element configured to be driven by the thin film transistor, in which the thin film transistor includes: a gate electrode; a gate insulating film covering the gate electrode; an oxide semiconductor layer provided on the gate insulating film; a source electrode and a drain electrode provided in a spaced, side-by-side relationship, the source electrode and the drain electrode each being connected to the oxide semiconductor layer; a first protective film covering the source electrode and the drain electrode, filling a gap between the source electrode and the drain electrode, and configured of a material including a silicon (Si) compound; a second protective film covering the first protective film and configured of a material including a metal compound; and a metal layer covering a region, over the second protective film, superposed on the gap between the source electrode and the drain electrode.

According to an embodiment of the present disclosure, there is provided an electronic apparatus provided with a display unit including a thin film transistor and a display element configured to be driven by the thin film transistor, the thin film transistor including: a gate electrode; a gate insulating film covering the gate electrode; an oxide semiconductor layer provided on the gate insulating film; a source electrode and a drain electrode provided in a spaced, side-by-side relationship, in which the source electrode and the drain electrode each are connected to the oxide semiconductor layer; a first protective film covering the source electrode and the drain electrode, filling a gap between the source electrode and the drain electrode, and configured of a material including a silicon (Si) compound; a second protective film covering the first protective film and configured of a material including a metal compound; and a metal layer covering a region, over the second protective film, superposed on the gap between the source electrode and the drain electrode.

According to an embodiment of the present disclosure, there is provided a method of manufacturing a thin film transistor including the following operations <1> to <7>:

<1> forming a gate electrode on a substrate;

<2> forming a gate insulating film covering the gate electrode;

<3> forming an oxide semiconductor layer on the gate insulating film;

<4> forming a source electrode and a drain electrode in a spaced, side-by-side relationship, in which the source electrode and the drain electrode each are connected to the oxide semiconductor layer;

<5> forming a first protective film using a material including a silicon compound, in which the first protective film covers the source electrode and the drain electrode and fills a gap between the source electrode and the drain electrode;

<6> forming a second protective film using a material including metal compound, in which the second protective film covers the first protective film; and

<7> forming a metal layer covering a region, over the second protective film, superposed on the gap between the source electrode and the drain electrode.

In the thin film transistor and the manufacturing method thereof, and the display unit and the electronic apparatus according to the above-described embodiments of the present disclosure, the gap between the source electrode and the drain electrode is filled by the first protective film including the silicon compound and covered by the metal layer. This restrains undesirable components such as water, a resin, and hydrogen from intruding into the oxide semiconductor layer. Further, presence of the first protective film avoids contact between a channel region of the oxide semiconductor and the second protective film. For example, if the second protective is made of aluminum oxide and in contact with the channel region of the oxide semiconductor, there may be possibility of oxygen diffusion into the channel region of the oxide semiconductor layer. Here, the first protective film is interposed between the channel region of the oxide semiconductor layer and the second protective film. This restrains the above-mentioned oxygen diffusion, leading to enhanced operation reliability.

According to the thin film transistor and the manufacturing method thereof, and the display unit and the electronic apparatus in the above-described embodiments of the present disclosure, it is possible to enhance operation reliability. It is to be noted that effects of the present disclosure are not limited to those described here, but may be any of effects described in the followings.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view illustrating a configuration of a thin film transistor according to a first embodiment of the present disclosure.

FIG. 2A is a cross-sectional view illustrating a process of a method of manufacturing the thin film transistor illustrated in FIG. 1.

FIG. 2B is a cross-sectional view illustrating a process following FIG. 2A.

FIG. 2C is a cross-sectional view illustrating a process following FIG. 2B.

FIG. 2D is a cross-sectional view illustrating a process following FIG. 2C.

FIG. 2E is a cross-sectional view illustrating a process following FIG. 2D.

FIG. 2F is a cross-sectional view illustrating a process following FIG. 2E.

FIG. 2G is a cross-sectional view illustrating a process following FIG. 2F.

FIG. 2H is a cross-sectional view illustrating a process following FIG. 2G.

FIG. 3 is a cross-sectional view illustrating a configuration of a thin film transistor according to a modification example of the first embodiment.

FIG. 4 is a cross-sectional view illustrating a configuration of a thin film transistor according to a second embodiment of the present disclosure.

FIG. 5A is a cross-sectional view illustrating a process of a method of manufacturing the thin film transistor illustrated in FIG. 4.

FIG. 5B is a cross-sectional view illustrating a process following FIG. 5A.

FIG. 5C is a cross-sectional view illustrating a process following FIG. 5B.

FIG. 5D is a cross-sectional view illustrating a process following FIG. 5C.

FIG. 5E is a cross-sectional view illustrating a process following FIG. 5D.

FIG. 5F is a cross-sectional view illustrating a process following FIG. 5E.

FIG. 6 is a diagram illustrating an overall configuration, including peripheral circuits, of a display unit according to the embodiments.

FIG. 7 is a diagram illustrating a circuit configuration of a pixel illustrated in FIG. 6.

FIG. 8 is a plan view schematically illustrating a configuration of a module including the display unit illustrated in FIG. 6.

FIG. 9 is a perspective view illustrating an appearance of a smart phone according to an application example of the display unit illustrated in FIG. 8.

### DETAILED DESCRIPTION

In the following, some embodiments of the present disclosure will be described in detail with reference to the accompanying drawings. It is to be noted that description will be made in the following order.

1. First Embodiment (a thin film transistor having a bottom-gate structure)

2. Modification Example of First Embodiment (an example with a channel protective film omitted)

3. Second Embodiment (a thin film transistor having a top-gate structure)

4. Third Embodiment (a display unit including the thin film transistor)

5. Application Example (a module including the display unit, and an electronic apparatus)

### First Embodiment

### Configuration of TFT 1

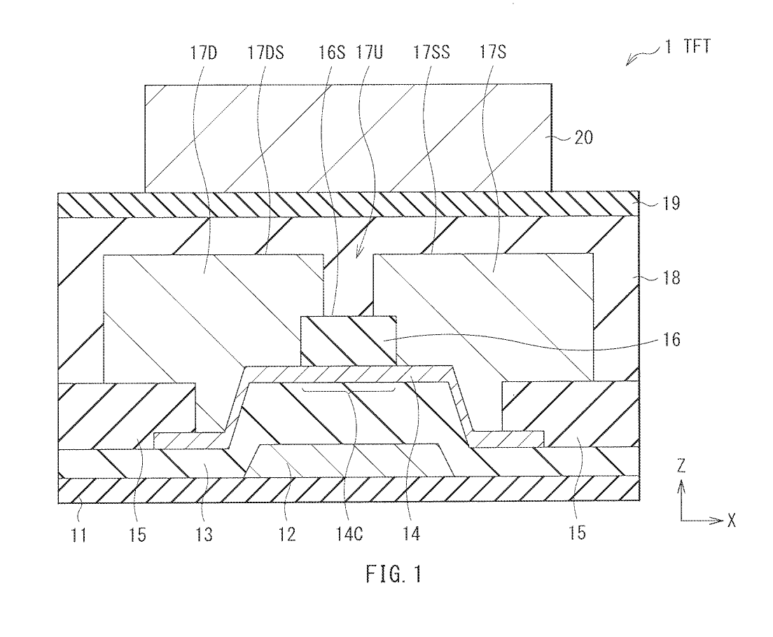

Description will now be given on a thin film transistor (TFT) 1 according to a first embodiment of the present disclosure with reference to FIG. 1. The TFT 1 may be used as a drive element in, for example, an active-matrix organic EL display unit or liquid crystal display unit.

The TFT 1 may have, for example, a so-called bottom-gate structure (an inverted stagger structure). The TFT 1 includes a gate electrode 12 and a gate insulating film 13. The gate electrode 12 may be formed on a selective region of a substrate 11. The substrate 11 may be configured of, for example, glass. The gate insulating film 13 may entirely cover the gate electrode 12 and the substrate 11. On a partial region over the gate insulating film 13, an oxide semiconductor layer 14 may be disposed so as to face the gate electrode 12 with the gate insulating film 13 in between. On the oxide semiconductor layer 14, a source electrode 17S and a drain electrode 17D may be provided. The source electrode 17S and the drain electrode 17D each are electrically connected to the oxide semiconductor layer 14. In the oxide semiconductor layer 14, a region corresponding to a gap between the source electrode 17S and the drain electrode 17D may be called a channel 14C. Directly on the channel 14C, a channel protective film 16 may be formed. The source electrode 17S and the drain electrode 17D are provided in a spaced, side-by-side relationship in an in-plane direction, with the channel protective film 16 in between. It is to be noted that an upper surface 17SS of the source electrode 17S and an upper surface 17DS of the drain electrode 17D may be heightwise positioned in a higher level than an upper surface 16S of the channel protective film 16. In other words, a distance between the upper surfaces 17SS and 17DS of the source/drain electrodes 17S and 17D and the substrate 11 may be larger than a distance between the upper surface 16S and the substrate 11. Accordingly, there may be formed a recess 17U in the gap between the source electrode 17S and the drain electrode 17D. The term ‘heightwise positioning’ as used here refers to positioning in a stacking direction (a Z-axis direction in FIG. 1) of components that constitute the TFT 1.

On the source electrode 17S and the drain electrode 17D, a first protective film 18 and a second protective film 19 may be formed in this order over the entirety. Hereinafter, the first protective film 18 and the second protective film 19 will be also referred to as the protective film 18 and the protective film 19, respectively. Here, the protective film 18 covers the source electrode 17S and the drain electrode 17D and also fills the recess 17U, that is, the gap between the source electrode 17S and the drain electrode 17D. The protective film 19 may be provided so as to cover at least a region, over the protective film 18, superposed on the channel 14C. Preferably, the protective film 19 may integrally and collectively cover a region superposed on the source electrode 17S, a region superposed on the drain electrode 17D, and a region superposed on the recess 17U.

The TFT 1 further includes a metal layer 20 covering a region, over the protective film 19, superposed on the gap between the source electrode 17S and the drain electrode 17D.

The gate electrode 12 is configured to control a carrier density in the oxide semiconductor layer 14 with a gate electrode (Vg) applied to the TFT 1. The gate electrode 12 also has a function as a wiring to supply potentials. The gate electrode 12 may be configured of, for example, a single substance of titanium (Ti), tungsten (W), molybdenum (Mo), aluminum, silver (Ag), or copper (Cu), or an alloy including one or more thereof. The gate electrode 12 may have a single-layer structure or a multi-layered structure. The multi-layered structure may be a stack of a plurality of layers all of which are made of a same kind of material, or a stack of a plurality of layers part or all of which are made of different kinds of materials. Specific but non-limited examples may include an aluminum alloy such as, but not limited to, an alloy of aluminum and neodymium (Nd) (Al—Nd alloy). Alternatively, the gate electrode 12 may be configured of a transparent conductive film such as, but not limited to, ITO (indium tin oxide), AZO (aluminum-doped zinc oxide), and GZO (gallium-doped zinc oxide).

The gate insulating film 13 may be, for example, a single-layer film made of one of a silicon oxide film (SiO₂), a silicon nitride film (SiN), and a silicon oxynitride film (SiON), or a stacked film made of two or more thereof. Alternatively, the gate insulating film 13 may be configured of, for example, aluminum oxide (Al₂O₃) or aluminum nitride (AlN).

The oxide semiconductor layer 14 is configured to constitute the channel 14C when the gate voltage is applied, and may be configured of, for example, an oxide semiconductor including at least one of indium (In), gallium (Ga), and zinc (Zn). Non-limited examples may include indium gallium zinc oxide (IGZO, InGaZnO). Also, the oxide semiconductor layer 14 may be configured of an oxide semiconductor including zirconium (Zr) or tin (Sn).

The channel protective film 16 may be, for example, a single-layer film made of one of a silicon oxide film, a silicon nitride film, and a silicon oxynitride film, or a stacked film made of two or more thereof. The channel protective film 16 has a function of protecting the channel 14C of the oxide semiconductor layer 14 against damage in a process of forming the source electrode 17S and the drain electrode 17D, for example.

The source electrode 17S and the drain electrode 17D may be separated from each other in a region corresponding to the channel 14C of the oxide semiconductor layer 14. Constituent materials of the source electrode 17S and the drain electrode 17D may be, for example, an equivalent or equivalents to those of the gate electrode 12. The source electrode 17S and the drain electrode 17D may have a multi-layered structure in which, for example, one or more metal layers including molybdenum (Mo) and one or more other metal layers including aluminum (Al) are stacked. Specific but non-limited examples may include a three-layer structure of a molybdenum film, an aluminum film, and a molybdenum film. It is to be noted that, instead of a lower molybdenum film in contact with the oxide semiconductor layer 14, a film made of a metal compound including oxygen, such as, but not limited to, ITO or titanium oxide, may be used. When an oxide semiconductor is in contact with a metal tending to deprive of oxygen, the oxide semiconductor is deprived of its oxygen to have defects. In general, when a metal is in contact with an oxide such as IGZO, the metal itself is oxidized by oxygen in the oxide. In other words, from viewpoint of the oxide such as IGZO, the oxide itself is reduced, which makes its characteristics as an oxide unstable. Accordingly, the use of a metal oxide as a conductive film produces an effect of reducing a gradient in oxygen concentration at an interface of the metal oxide and the oxide such as IGZO, which restrains oxygen in the oxide such as IGZO from diffusing. This makes it possible to stabilize characteristics of the oxide such as IGZO.

The protective film 18 is configured of a material including a silicon (Si) compound, and is also called a passivation film. Non-limited examples of the silicon compound may include a silicon oxide, a silicon nitride, and a silicon oxynitride. A thickness of the protective film 18 may be, for example, 50 nm to 2000 nm both inclusive.

The protective film 18 may have a function of electrically insulating the source electrode 17S and the drain electrode 17D from their surroundings. Also, the protective film 18 may have a function of blocking a disturbance substance such as oxygen diffusing from the protective film 19 toward the channel 14C in a case with the protective film 19 made of an oxide as an upper layer.

Here, preferably, the protective film 18 may have more satisfactory film quality than that of the channel protective film 16. The term “satisfactory” as used here refers to ability to restrain hydrogen included in an atmosphere of a film formation process or in the air when used from reducing an oxide semiconductor. Alternatively, the term “satisfactory” refers to ability to restrain oxygen in an oxide semiconductor or in a transparent conductive metal oxide wiring from separating due to heat treatment or the like. Also, preferably, an upper surface of the protective film 18 may have high planarity. This makes it possible to reduce a variation in thickness of the protective film 19 formed thereon or stepwise disconnection of the protective film 19, making the protective film 19 more uniform and denser. Accordingly, the protective film 18 may preferably formed by a vapor phase growth method such as, but not limited to, a CVD (chemical vapor deposition) method. The protective film 18 may be formed on a surface having relatively large unevenness under which the source electrode 17S and the drain electrode 17D are formed on the oxide semiconductor layer 14. A silicon compound film formed by a vapor phase growth method may follow such unevenness to form an upper surface having high planarity. It is to be noted that the protective film 18 may be improved in density and film quality by techniques such as, but not limited to, use of a higher deposition temperature or optimization of a gas type used in deposition.

The protective film 19 covers the protective film 18 and is configured of a material including a metal compound. Non-limited examples of the metal compound may include one or more of a metal oxide, a metal nitride, and a metal oxynitride that include one or both of aluminum (Al) and titanium (Ti). Specific but non-limited examples may include aluminum oxide (Al₂O₃), titanium oxide, aluminum nitride (ALN), and titanium oxide (TiN). A thickness of the protective film 19 may be, for example, 10 nm to 300 nm both inclusive. The protective film 19 is configured to restrain moisture or hydrogen from mixing into the oxide semiconductor layer 14.

The protective film 19 may have a function of electrically insulating the source electrode 17S and the drain electrode 17D from their surroundings, similarly to the protective film 18. Also, the protective film 19 may have a function of reducing damage to lower structures in forming the metal layer 20. Further, the protective film 19 may have a function of supplying the protective film 18 with oxygen during its manufacturing process, when the protective film 19 is configured of, for example, Al₂O₃. Specifically, in forming the protective film 19, excessive oxygen atoms that constitute the protective film 19 may be supplied to the protective film 18 made of a silicon compound such as SiO₂. In other words, oxygen fills an oxygen-deficiency portion in vicinity of a surface of the protective film 18. Such supply of oxygen atoms may contribute to recovery of characteristics or prevention of degradation of the protective film 18, resulting in recovery of TFT characteristics or prevention in degradation in TFT characteristics.

The protective film 18 and the protective film 19 may strongly adhere to each other. For example, when the protective film 18 is configured of a silicon oxide and the protective film 19 is configured of an aluminum oxide, the protective films 18 and 19 may attain relatively strong adhesion to each other as well as a small difference between expansion coefficients of the protective films 18 and 19. This makes it unlikely for the protective films 18 and 19 to separate from each other, attaining excellent long-term reliability.

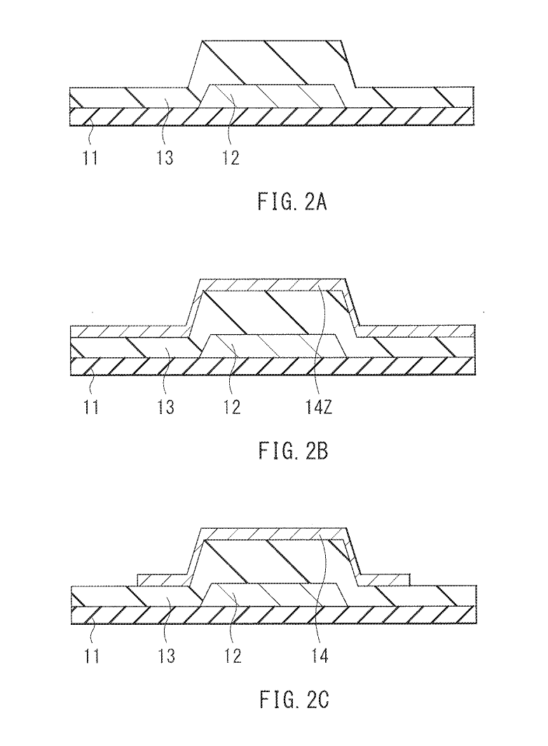

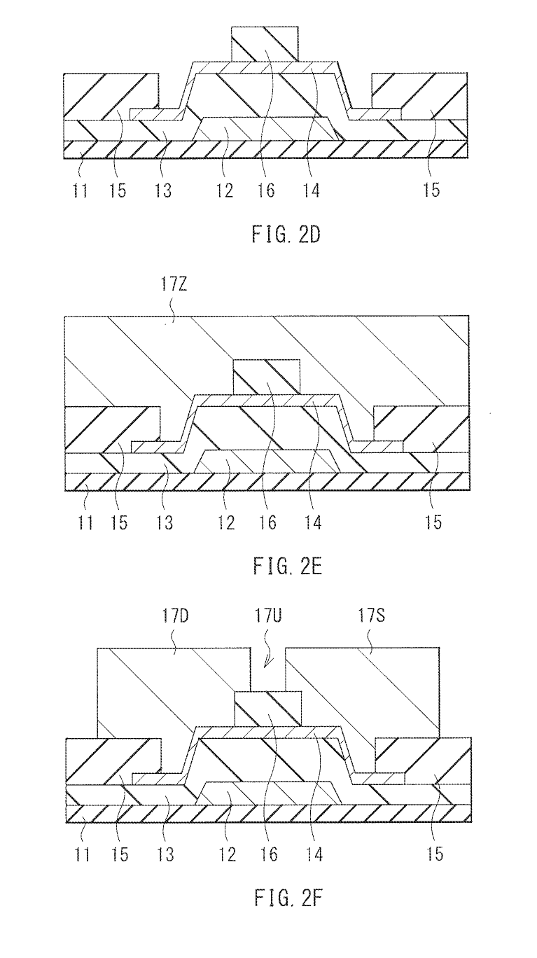

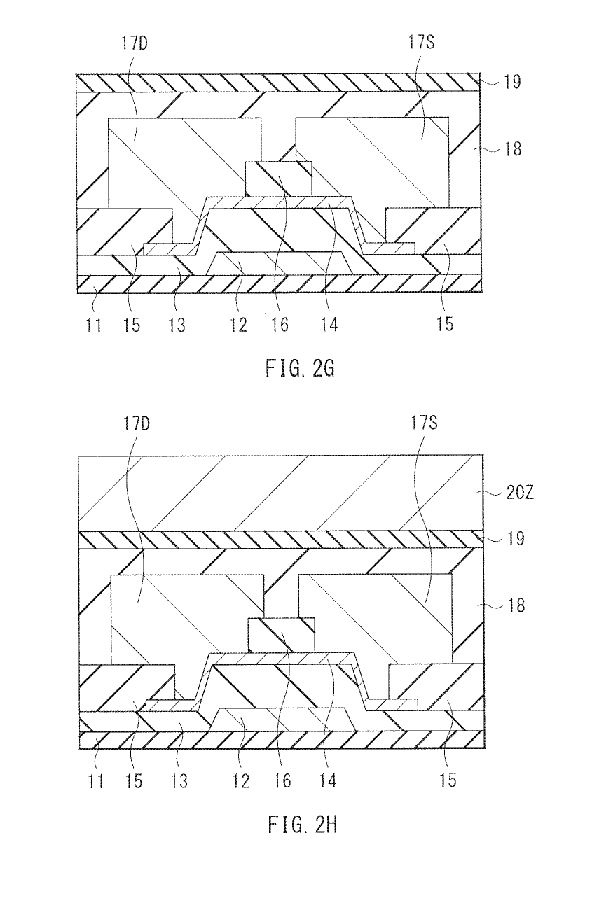

The metal layer 20 may be configured of a nonmagnetic metal such as, but not limited to, aluminum. The metal layer 20 may have a multi-layered structure in which one or more metal films including molybdenum (Mo) and one or more other metal films including aluminum (Al) are stacked, similarly to the source electrode 17S and the drain electrode 17D. Specific but non-limited example may include a three-layer structure of a molybdenum film, an aluminum film, and a molybdenum film. The metal layer 20 may serve as a shield to restrain a disturbance substance such as, but not limited to water, hydrogen, or a resin from permeating the channel 14C. Accordingly, the metal layer 20 may preferably include regions that are superposed on part of the source electrode 17S and part of the drain electrode 17D in a thickness direction.

[Method of Manufacturing TFT 1]Next, description will be made on a method of manufacturing the TFT 1 with reference to FIGS. 2A to 2H. FIGS. 2A to 2H each illustrate, in cross-section, part of the method of manufacturing the TFT 1.

First, referring to FIG. 2A, the gate electrode 12 is formed on a selective region of the substrate 11. Specifically, the above-mentioned material, for example, molybdenum, is deposited on the entire surface of the substrate 11 by, for example, a sputtering method, and then the deposited film is patterned by, for example, photolithography. Thus, the gate electrode 12 is obtained.

Subsequently, the gate insulating film 13 is deposited by, for example, a CVD method or a sputtering method so as to entirely cover the substrate 11 and the gate electrode 12. For example, when a silicon nitride film is formed by a plasma CVD method, a mixed gas including silane (SiH₄), ammonia (NH₃), and nitrogen (N₂) may be used as a material gas. Alternatively, when a silicon oxide film is formed as the gate insulating film 13 by a plasma CVD method, a mixed gas including silane and dinitrogen oxide (N₂O) may be used as a material gas. Further, when the gate insulating film 13 is formed by a reactive plasma sputtering method, silicon may be used as a target material, and oxygen, vapor, nitrogen, or the like may be used as a discharge atmosphere of sputtering.

Next, referring to FIG. 2B, an oxide semiconductor film 14Z that eventually serves as the oxide semiconductor layer 14 is deposited by, for example, a sputtering method. Specifically, in a case with the oxide semiconductor film 14Z made of IGZO, reactive sputtering may be carried out with use of IGZO ceramic as a target. At this occasion, for example, in a DC sputter device, a chamber may be evacuated to a predetermined degree of vacuum, i.e., 1×10⁻⁴ Pa or less. Thereafter, the above-mentioned target and the substrate 11 may be arranged in the chamber, while a mixed gas of, for example, argon (Ar) and oxygen (O₂) may be introduced in the chamber for plasma discharge. In this way, the oxide semiconductor film 14Z made of IGZO may be deposited on the gate insulating film 13. Alternatively, in a case with the oxide semiconductor film 14Z with use of zinc oxide (ZnO), an RF sputtering method with use of zinc oxide ceramic as a target may be applied. In another alternative, the oxide semiconductor film 14Z made of zinc oxide may be formed by application of a DC sputtering method with use of a metal target made of zinc (Zn) in an atmosphere of a mixed gas including argon and oxygen. A carrier density in the oxide semiconductor film 14Z may be controlled by, for example, changing a flow ratio of argon and oxygen in the chamber at the time of deposition.

Next, referring to FIG. 2C, the oxide semiconductor film 14Z is patterned into a desired shape to form the oxide semiconductor layer 14. Specifically, part of the oxide semiconductor film 14Z is selectively removed by a photolithography process and an etching process. In the etching process, since the oxide semiconductor film 14Z is acid-soluble and alkali-soluble, a wet etching method may be used in general. However, a dry etching method may be also possible.

It is to be noted that, when the oxide semiconductor film 14Z is configured of a crystalline material having higher ratio of indium or tin than those of other constituent elements, crystallization annealing may be preferably carried out in a phase after deposition. In this way, the oxide semiconductor film 14Z is allowed to obtain resistance to an etching solvent. A desirable thickness of the oxide semiconductor film 14Z may be 5 nm to 100 nm both inclusive, in consideration of efficiency of oxygen supply by annealing after deposition.

Subsequently, referring to FIG. 2D, the channel protective film 16 is formed on the oxide semiconductor layer 14 in a region superposed on the gate electrode 12. Specifically, on the oxide semiconductor layer 14, the channel protective film 16 made of the above-mentioned material is deposited by, for example, a CVD method or a sputtering method. Then, the channel protective film 16 is patterned into a desired shape by, for example, dry etching with use of a photolithography method. At this occasion, on the gate insulating film 13 exposed adjacent to both ends of the oxide semiconductor layer 14, an insulating film 15 may be formed simultaneously. The insulating film 15 may be configured of a similar material to that of the channel protective film 16. Moreover, the deposition of the channel protective film 16 may be preferably carried out at a low temperature of 250° C. or less, in consideration of damage to the oxide semiconductor layer 14 as a base.

Next, referring to FIG. 2E, a metal film 17Z is deposited by, for example, a sputtering method so as to cover the oxide semiconductor layer 14, the channel protective film 16, and the insulating film 15. Specifically, a molybdenum film, an aluminum film, and a molybdenum film may be sequentially stacked to form the metal film 17Z having a three-layer structure. Thereafter, the above-mentioned metal film 17Z is patterned by a wet etching method with use of a mixed liquid including, for example, phosphoric acid, nitric acid, and acetic acid. In this way, as illustrated in FIG. 2F, the source electrode 17S and the drain electrode 17D are obtained. At this occasion, the gap between the source electrode 17S and the drain electrode 17D, that is, the recess 17U is formed directly above the channel 14C.

Subsequently, referring to FIG. 2G, the protective film 18 is formed by, for example, a vapor phase growth method such as, but not limited to, a CVD method so as to cover the source electrode 17S and the drain electrode 17D and to fill the recess 17U. It is to be noted that the protective film 18 may be improved in density and film quality by techniques such as an increase in a deposition temperature or optimization of a gas type used at the time of deposition.

Further, the protective film 19 is formed with use of the above-mentioned material including the metal compound by, for example, a sputtering method or the like so as to cover the protective film 18.

Subsequently, referring to FIG. 2H, a metal film 20Z is formed with use of a nonmagnetic metal such as, but not limited to, aluminum by a sputtering method or the like so as to entirely cover the protective film 19. Thereafter, the metal film 20Z is patterned into a desired shape by, for example, a wet etching method. Thus, the metal layer 20 is obtained (refer to FIG. 1). The metal layer 20 covers the region, over the protective film 19, superposed on the recess 17U. In this way, the TFT 1 is completed.

[Workings and Effects of TFT 1]

As described above, in the TFT 1 according to the present embodiment, the TFT 1 has a structure in which the channel protective film 16, the protective film 18, the protective film 19, and the metal film 20 are sequentially stacked on the channel 14C. Hence, in the TFT 1, it is possible to protect the TFT 1 sufficiently, acquiring high operation reliability and excellent long-term reliability.

Here, in general, a TFT including an oxide semiconductor layer is likely to vary in operation characteristics by an oxidation-reduction reaction due to an atmosphere in manufacturing processes or an atmosphere in use environment. Various measures have been proposed so far, but none of them has been sufficient.

Thus, the TFT 1 according to the present embodiment adopts a configuration in which the metal layer 20 is provided above the channel 14C, while the protective films 18 and 19 having insulating properties are disposed between the metal layer 20 and the source/drain electrodes 17S and 17D. In the TFT 1 thus configured, the channel 14C, the source electrode 17S and the drain electrode 17D are sufficiently sealed by the protective films 18 and 19. This makes it possible to reduce influences of outside air on the channel 14C. Hence, it is possible to maintain high operation reliability for a long period of time even in, for example, a high temperature and high humidity environment. In other words, relation between a gate voltage applied and a drain current obtained becomes stable, leading to considerably high operation reproducibility.

Moreover, in the TFT 1, the protective film 19 configured of aluminum oxide or the like is provided between the metal layer 20 and the protective film 18. Hence, it is possible to prevent damage to lower structures including the protective film 18 and the channel 14C in forming the metal layer 20. This is because the protective film 19 may serve as an etching stopper in forming the metal film 20Z by a sputtering method or may serve as an etching stopper in patterning the metal film 20Z by a wet etching method or the like. In the meanwhile, the protective film 18 may block oxygen diffusing from the constituent materials of the protective film 19, i.e., aluminum oxide or the like, preventing the oxygen from intruding into the channel 14C.

Further, the silicon compound that constitutes the protective film 18, i.e., silicon oxide or the like, may follow the unevenness of a surface on which the protective film 18 is formed, allowing an upper surface of the protective film 18 to have relatively high planarity. Accordingly, it is possible to form, on the protective film 18 having planarity, the protective film 19 made of aluminum oxide, which has difficulty in uniform formation on an uneven surface. Thus, the protective film 19 is likely to become a dense, continuous film.

Also, the presence of the protective film 18 allows an electric field gradient in vicinity of the channel 14C to be stabilized at the time of operation of the TFT 1. Accordingly, in the TFT 1, a threshold voltage is unlikely to be shifted, making it possible to obtain high operation reliability.

Further, in a case with the protective film 18 made of a silicon oxide film and the protective film 19 made of an aluminum oxide film, it is possible to exhibit excellence both in long-term reliability and in operation reliability. This is because of considerably high sealing property available thanks to high adhesion between the protective films 18 and 19, and a small difference in expansion coefficients thereof.

### 2. Modification Example

### Configuration of TFT 1A

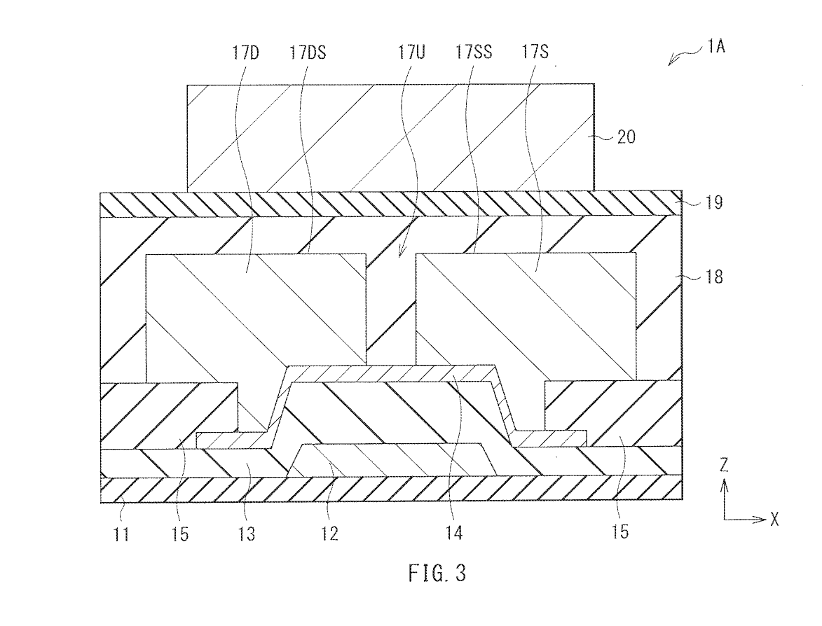

FIG. 3 illustrates a cross-sectional configuration of a main part of a TFT 1A according to a modification example of the above-described first embodiment. In the TFT 1A, no channel protective film is disposed directly on the channel 14C. Otherwise, the TFT 1A may have a similar configuration to that of the TFT 1 according to the first embodiment.

[Workings and Effects of TFT 1A]

In the TFT 1A, workings and effects similar to those of the above-described TFT 1 may be attained, except for those in terms of the channel protective film, by reducing damage to the channel 14C by means of, for example, adjustment of etching conditions in forming the source electrode 17S and the drain electrode 17D.

### 3. Second Embodiment

### Configuration of TFT 2

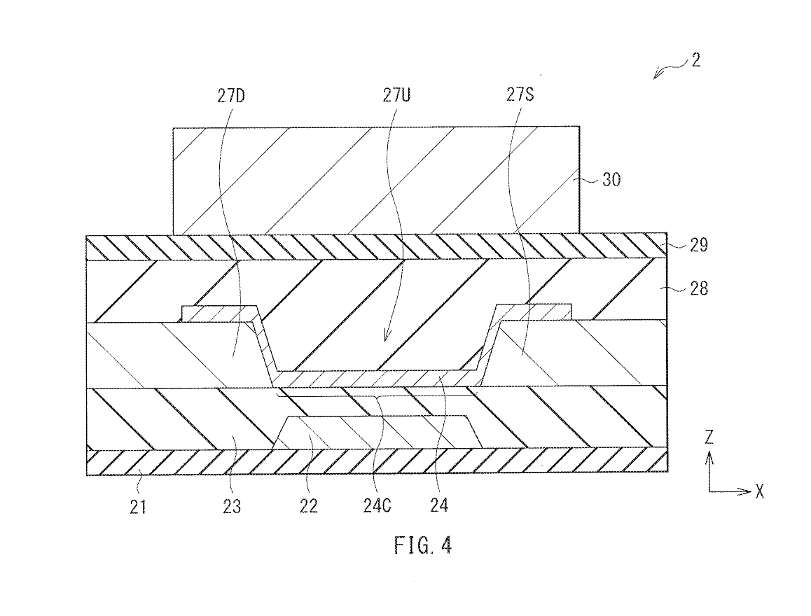

FIG. 4 illustrates a cross-sectional configuration of a TFT 2 according to a second embodiment of the present disclosure. The TFT 2, similarly to the TFT 1 according to the above-described first embodiment, may be used as a drive element in, for example, an active-matrix organic EL display unit or the like. Moreover, in the TFT 2, similarly to the above-described TFT 1, a gate electrode 22 and an oxide semiconductor layer 24 face each other with a gate insulating film 23 in between; and a source electrode 27S and a drain electrode 27D are provided so that they each are electrically connected to the oxide semiconductor layer 24. Further, the TFT 2 includes protective films 28 and 29 that are formed in the stacked film formation process as described above.

The TFT 2 according to the present embodiment may have a so-called top gate structure (a staggered structure). The TFT 2 may include the gate electrode 22 and the gate insulating film 23. The gate electrode 22 may be formed on a selective region of a substrate 21. The substrate 21 may be configured of, for example, glass. The gate insulating film 23 may entirely cover the gate electrode 22 and the substrate 21. On the gate insulating film 23, the source electrode 27S and the drain electrode 27D may be provided in a spaced, side-by-side relationship, with a region directly above the gate electrode 22 in between.

In a recess 27U as a gap between the source electrode 27S and the drain electrode 27D, the oxide semiconductor layer 24 may be provided so as to continuously cover a surface of the gate insulating film 23, an end surface of the source electrode 27S, and an end surface of the drain electrode 27D. The oxide semiconductor layer 24 may include a region that is in contact with the gate insulating film 23, or a region that is positioned directly above the gate electrode 22. This region is called a channel 24C. A first protective film (the protective film) 28 and a second protective film (the protective film) 29 may be formed in this order over the entirety so as to cover the channel 24C, the source electrode 27S, and the drain electrode 27D. The TFT 2 further includes a metal layer 30 covering a region, over the protective film 29, superposed with the channel 24C.

The substrate 21, the gate electrode 22, the gate insulating film 23, the oxide semiconductor layer 24, the channel 24C, the source electrode 27S, the drain electrode 27D, the protective film 28, the protective film 29, and the metal layer 30 in the TFT 2 correspond to the substrate 11, the gate electrode 12, the gate insulating film 13, the oxide semiconductor layer 14, the channel 14C, the source electrode 17S, the drain electrode 17D, the protective film 18, the protective film 19, and the metal layer 20, respectively.

[Method of Manufacturing TFT 2]

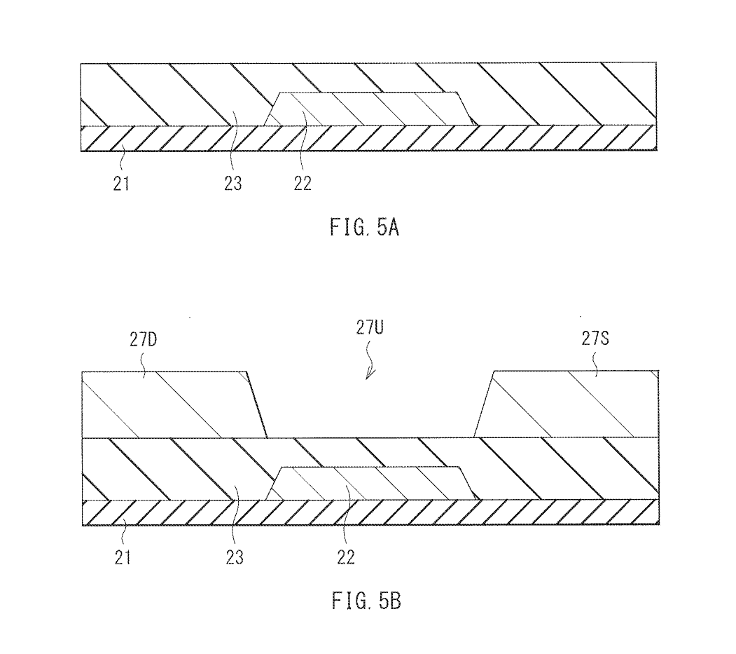

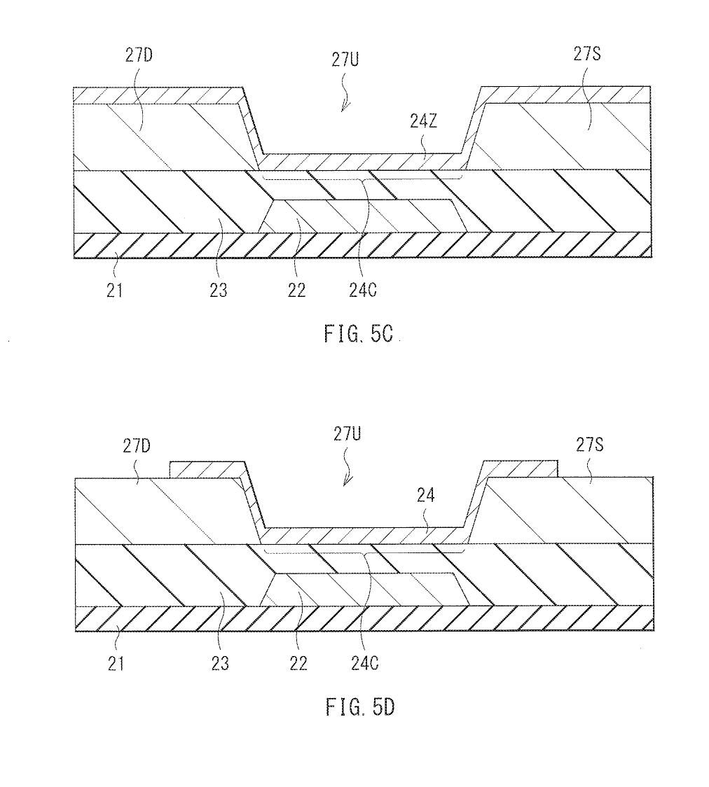

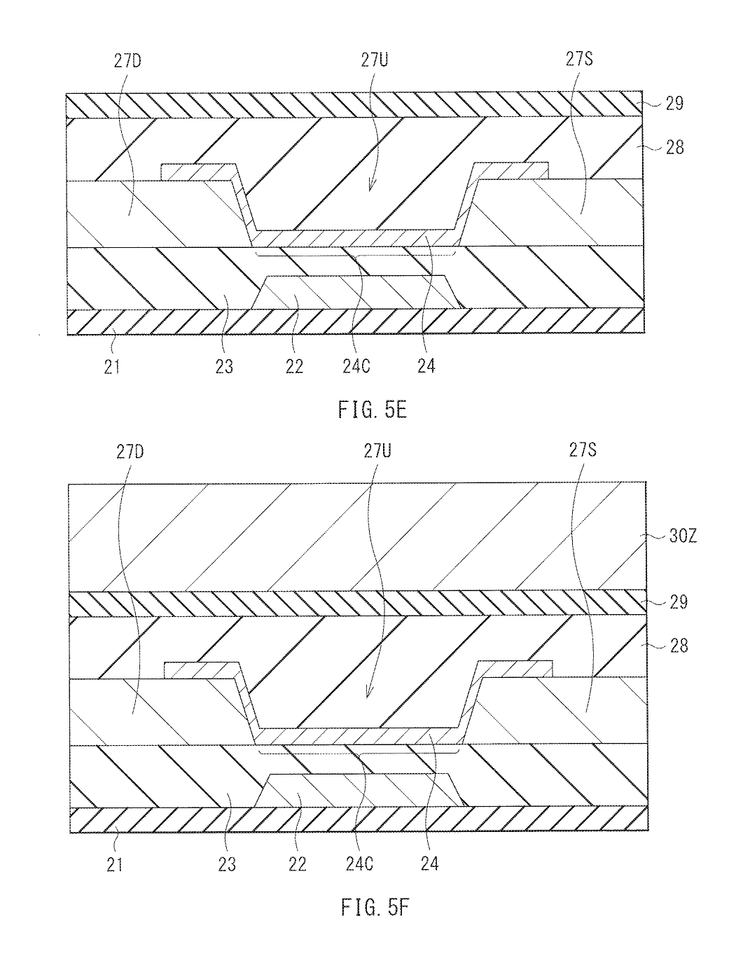

FIGS. 5A to 5F illustrate a method of manufacturing the TFT 2. The TFT 2 may be manufactured, for example, as follows.

First, referring to FIG. 5A, the gate electrode 22 is formed on a selective region of the substrate 21. Specifically, the above-mentioned material, for example, molybdenum, is deposited on the entire surface of the substrate 21 by, for example, a sputtering method, and then the deposited film is patterned by, for example, photolithography. Thus, the gate electrode 22 is obtained.

Subsequently, the gate insulating film 23 is deposited by, for example, a CVD method or a sputtering method so as to entirely cover the substrate 21 and the gate electrode 22.

Thereafter, referring to FIG. 5B, the source electrode 27S and the drain electrode 27D are formed on the gate insulating film 23 so as to be in a spaced, side-by-side relationship with the region directly above the gate electrode 22 in between. Thus, the recess 27U is formed.

Subsequently, referring to FIG. 5C, an oxide semiconductor film 24Z that eventually serves as the oxide semiconductor layer 24 is deposited by, for example, a sputtering method, similarly to the above-described oxide semiconductor film 14Z. Here, the oxide semiconductor film 24Z is deposited so as to cover the recess 27U, an upper surface and a side surface of the source electrode 27S, and an upper surface and a side surface of the drain electrode 27D.

Next, referring to FIG. 5D, the oxide semiconductor film 24Z is patterned into a desired shape to form the oxide semiconductor layer 24. Specifically, part of the oxide semiconductor film 24Z is selectively removed by a photolithography process and an etching process, similarly to the case of forming the oxide semiconductor layer 14.

After this, referring to FIG. 5E, the protective film 28 is formed, for example, in a similar manner to the above-described protective film 18, so as to entirely cover the oxide semiconductor 24, the source electrode 27S, and the drain electrode 27D. Further, the protective film 29 is formed in a similar manner to the above-described protective film 19 so as to cover the protective film 28.

Subsequently, referring to FIG. 5F, the metal film 30Z is formed in a similar manner to the above-described metal film 20Z so as to entirely cover the protective film 29. Finally, the metal film 30Z is patterned into a predetermined shape by, for example, a wet etching method. Thus, the metal layer 30 is obtained (refer to FIG. 4). The metal layer 30 covers the region, over the protective film 29, superposed on the recess 27U. In this way, the TFT 2 is completed.

[Workings and Effects of TFT 2]

As described above, also in the TFT 2 according to the present embodiment, the TFT 2 has a structure in which the protective film 28, the protective film 29, and the metal layer 30 are sequentially stacked on the channel 24C. Hence, it is possible to obtain similar workings and effects to those of the TFT 1. That is, in the TFT 2, it is possible to protect the channel 24C sufficiently, acquiring high operation reliability and excellent long-term reliability.

### 4. Third Embodiment

### Configuration of Display Unit and Configuration of Pixel Circuit

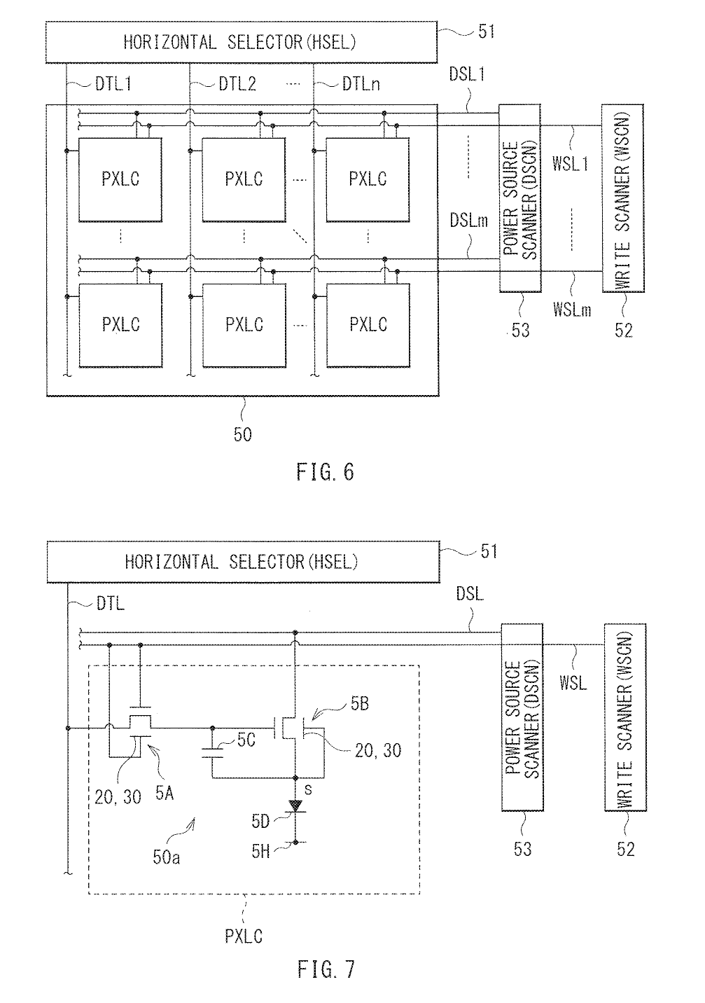

Next, description will move on to an overall configuration of a display unit and a configuration of a pixel circuit using the above-described TFT 1, 1A or 2. FIG. 6 illustrates an overall configuration, including peripheral circuits, of a display unit used as an organic EL display. As illustrated in FIG. 6, in the display unit, a display region 50 may be formed on a substrate (the substrate 11 or 21). The display region 50 may include a plurality of pixels PXLC arrayed in a matrix. The pixels PXLC each may include an organic EL element. Around the display region 50, there may be provided a horizontal selector (HSEL) 51 as a signal line drive circuit, a write scanner (WSCN) 52 as a scan line drive circuit, and a power source scanner (DSCN) 53 as a power line drive circuit.

The display region 50 may include a plurality of (n; n is an integer) signal lines DTL1 to DTLn in a column direction, and a plurality of (m; m is an integer) scan lines WSL1 to WSLm and power lines DSL1 to DSLm in a row direction. Each of the pixels PXLC may be disposed at an intersection of the signal lines DTL and the scan lines WSL. The pixels PXLC each may be one of the pixels corresponding to R, G, and B. Each of the data lines DTL may be connected to the horizontal selector 51, which is configured to supply each of the signal lines DTL with picture signals. Each of the scan lines WSL may be connected to the write scanner 52, which is configured to supply each of the scan lines WSL with scan signals (selection pulses). Each of the power lines DSL may be connected to the power source scanner 53, which is configured to supply each of the power lines DSL with power source signals (control pulses).

FIG. 7 illustrates a specific example of a circuit configuration in the pixel PXLC. Each of the pixels PXLC may include a pixel circuit 50a including an organic EL element 5D. The pixel circuit 50a may be an active-matrix drive circuit including a sampling transistor 5A, a drive transistor 5B, a retention capacitor 5C, and the organic EL element 5D. Among these, the transistor 5A (or the transistor 5B) corresponds to the TFT 1, 1A, or 2.

The sampling transistor 5A may include a gate, a source, and a drain; the gate may be connected to the associated scan line WSL; one of the source and the drain may be connected to the associated signal line DTL; and the other may be connected to a gate of the drive transistor 5B. The drive transistor 5B may include a gate and a source; the gate may be connected to the associated power line DSL; and the source may be connected to an anode of the organic EL element 5D. A cathode of the organic EL element 5D may be connected to a ground wiring 5H. It is to be noted that the ground wiring 5H may be connected commonly to all the pixels PXLC. The retention capacitor 5C may be connected between the source and the gate of the drive transistor 5B.

The sampling transistor 5A is configured to become conductive in response to the scan signal (the selection pulse) supplied from the scan line WSL, to sample a signal potential of the picture signal supplied from the signal line DTL, and to allow the retention capacitor 5C to store the sampled signal potential. The drive transistor 5B is configured to receive current supply from the power line DSL that is set to a predetermined first potential (not illustrated), and to supply the organic EL element 5D with a drive current according to the signal potential stored in the retention capacitor 5C. The organic EL element 5D is configured to emit light with intensity according to the signal potential of the picture signal, by means of the drive current supplied from the drive transistor 5B.

In such a circuit configuration, the sampling transistor 5A becomes conductive in response to the scan signal (the selection pulse) supplied from the scan line WSL. Thereby, the signal potential of the picture signal supplied from the signal line DTL is sampled, and the signal potential thus sampled is stored in the retention capacitor 5C. In the meanwhile, the drive transistor 5B is supplied with a current from the power line DSL set to the above-mentioned first potential, allowing a drive current to be supplied to the organic EL element 5D (each of the organic EL elements in red, green, and blue) according to the signal potential stored in the retention capacitor 5C. Then, the organic EL elements 5D each emit light with intensity according to the signal potential of the picture signal, by means of the drive current thus supplied. In this way, in the display unit, picture display is performed based on the picture signal.

In the pixel circuit 50a of the pixel PXLC, a current may keep flowing constantly through the drive transistor 5B during light emission of the organic EL element 5D. Accordingly, degradation in characteristics of a channel in the drive transistor 5B has been confirmed due to application of excessive positive voltage stress to a metal layer adjacent to a protective film having poor film quality. Here, in the display unit according to the embodiment of the present disclosure, a potential of the metal layer (the metal layer 20 or 30) in the drive transistor 5B may be fixed to a source potential as a zero volt potential, or to a cathode potential. On the other hand, regarding other switching transistors (the sampling transistor 5A), the potential of the metal layer (the metal layer 20 or 30) may be adjusted to a potential of a gate electrode (the gate electrode 12 or 22), allowing a current off state to be stabilized. Moreover, since the sampling transistor 5A used as a switching transistor has a tendency of negative shift of a threshold voltage, there may be possibility of an increase in leak currents. Accordingly, in the display unit according to the embodiment of the present disclosure, it is therefore desirable to adopt a structure capable of controlling a carrier density on the back channel side, by allowing the potential of the metal layer (the metal layer 20 or 30) to be short-circuited to the gate electrode (the gate electrode 12 or 22), in controlling the threshold voltage (refer to FIG. 7).

### 5. Application Example

In the following, description will be given on application examples of the above-described display unit to electronic apparatuses. Non-limited examples of electronic apparatuses may include a television device, a digital camera, a notebook computer, a portable terminal device such as, but not limited to, a smart phone, and a video camera. In other words, the above-described display unit may be applied to electronic apparatuses in various fields to perform display of images or pictures based on picture signals inputted from outside or picture signals generated inside.

[Module]

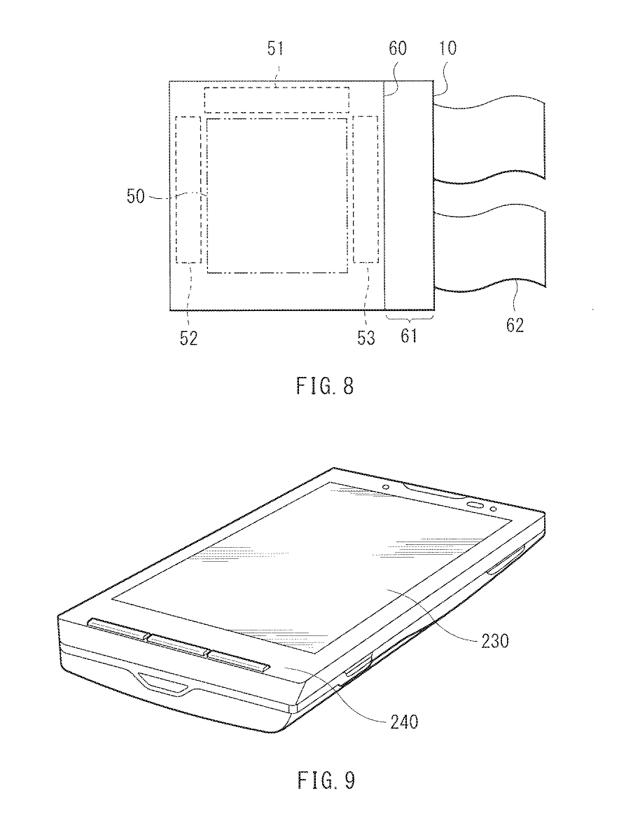

The above-described display unit may be incorporated, in a form of a module as illustrated in FIG. 8, in various electronic apparatuses such as an application example, which will be exemplified below. The module may include, for example, a region 61 exposed beyond the sealing substrate 60, along one side of a substrate 10 (or the substrate 11 or 21). In the exposed region 61, there may be provided external connection terminals (not illustrated) that are extended from wirings of the horizontal selector 51, the write scanner 52, and the power source scanner 53. On the external connection terminals, a flexible printed circuit (FPC) 62 for signal input and output may be provided.

### Application Example

FIG. 9 illustrates an appearance of a smart phone to which the display unit according to the above-described example embodiment may be applied. The smart phone may include, for example, a display section 230 and a non-display section 240. The display section 230 may be configured of the display unit according to the above-described example embodiment.

Although description of the present disclosure has been made by giving the example embodiments as mentioned above, the contents of the present disclosure are not limited to the above-mentioned example embodiments and may be modified in a variety of ways. For example, a material and a thickness of each layer as described in the above-mentioned example embodiments are not limitative, but other materials and other thicknesses may be adopted.

Moreover, the components of the TFT according to the above-described example embodiments are not limited to single-layer structures, but multi-layered structures may be also possible. In this case, the multi-layered structure may be a stack of a plurality of layers made of a same kind of material or a stack of a plurality of layers made of different kinds of materials.

Furthermore, in the above-described example embodiments, description has been given on a case of an active-matrix display unit. However, the present technology may be applicable to a passive-matrix display unit. In addition, a configuration of the signal line drive circuit for active-matrix driving is not limited to as exemplified in the above-described example embodiments. A capacitor or a transistor may be added as necessary. In this case, according to changes or alterations of the signal line drive circuit, an additional drive circuit may be provided in addition to the horizontal selector (HSEL) 51, the write scanner (WSCN) 52, and the power source scanner (DSCN) 53.

It is to be noted that effects described in the specification are merely exemplified and not limited thereto, and effects of the present disclosure may be other effects or may further include other effects. It is possible to achieve at least the following configurations from the above-described example embodiments of the disclosure.

(1)

A thin film transistor, including:

a gate electrode;

a gate insulating film covering the gate electrode;

an oxide semiconductor layer provided on the gate insulating film;

a source electrode and a drain electrode provided in a spaced, side-by-side relationship, the source electrode and the drain electrode each being connected to the oxide semiconductor layer;

a first protective film covering the source electrode and the drain electrode, filling a gap between the source electrode and the drain electrode, and configured of a material including a silicon (Si) compound;

a second protective film covering the first protective film and configured of a material including a metal compound; and

a metal layer covering a region, over the second protective film, superposed on the gap between the source electrode and the drain electrode.

(2)

The thin film transistor according to (1),

wherein the material including the silicon compound includes one or more of a silicon oxide, a silicon nitride, and a silicon oxynitride, and

the metal compound includes one or more of an oxide, a nitride, and an oxynitride that include one or both of aluminum (Al) and titanium (Ti).

(3)

The thin film transistor according to (1) or (2),

wherein the oxide semiconductor layer includes an oxide including one or more elements of zinc (Zn), indium (In), gallium (Ga), zirconium (Zr), and tin (Sn).

(4)

The thin film transistor according to any one of (1) to (3),

wherein the second protective film integrally and collectively covers a region superposed on the source electrode, a region superposed on the drain electrode, and the region superposed on the gap between the source electrode and the drain electrode.

(5)

The thin film transistor according to any one of (1) to (4),

wherein the first protective film is formed by a vapor phase growth method, and

the second protective film is formed by a sputter deposition method.

(6)

The thin film transistor according to any one of (1) to (5), further including a third protective film covering a region, over the oxide semiconductor layer, corresponding to the gap between the source electrode and the drain electrode.

(7)

The thin film transistor according to any one of (1) to (6),

wherein the source electrode and the drain electrode each have a multi-layered structure in which one or more first metal films including molybdenum (Mo) and one or more second metal films including aluminum (Al) are stacked.

(8)

The thin film transistor according to any one of (1) to (7),

wherein the metal layer has a multi-layered structure in which one or more first metal films including molybdenum (Mo) and one or more second metal films including aluminum (Al) are stacked.

(9)

A display unit provided with a thin film transistor and a display element configured to be driven by the thin film transistor, the thin film transistor including:

a gate electrode;

a gate insulating film covering the gate electrode;

an oxide semiconductor layer provided on the gate insulating film;

a source electrode and a drain electrode provided in a spaced, side-by-side relationship, the source electrode and the drain electrode each being connected to the oxide semiconductor layer;

a first protective film covering the source electrode and the drain electrode, filling a gap between the source electrode and the drain electrode, and configured of a material including a silicon (Si) compound;

a second protective film covering the first protective film and configured of a material including a metal compound; and

a metal layer covering a region, over the second protective film, superposed on the gap between the source electrode and the drain electrode.

(10)

An electronic apparatus provided with a display unit including a thin film transistor and a display element configured to be driven by the thin film transistor, the thin film transistor including:

a gate electrode;

a gate insulating film covering the gate electrode;

an oxide semiconductor layer provided on the gate insulating film;

a source electrode and a drain electrode provided in a spaced, side-by-side relationship, the source electrode and the drain electrode each being connected to the oxide semiconductor layer;

a first protective film covering the source electrode and the drain electrode, filling a gap between the source electrode and the drain electrode, and configured of a material including a silicon (Si) compound;

a second protective film covering the first protective film and configured of a material including a metal compound; and

a metal layer covering a region, over the second protective film, superposed on the gap between the source electrode and the drain electrode.

(11)

A method of manufacturing a thin film transistor, including:

forming a gate electrode on a substrate;

forming a gate insulating film covering the gate electrode;

forming an oxide semiconductor layer on the gate insulating film;

forming a source electrode and a drain electrode in a spaced, side-by-side relationship, the source electrode and the drain electrode each being connected to the oxide semiconductor layer;

forming a first protective film using a material including a silicon compound, the first protective film covering the source electrode and the drain electrode and filling a gap between the source electrode and the drain electrode;

forming a second protective film using a material including metal compound, the second protective film covering the first protective film; and

forming a metal layer covering a region, over the second protective film, superposed on the gap between the source electrode and the drain electrode.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film transistor, comprising:
a gate electrode;
a gate insulating film covering the gate electrode;
an oxide semiconductor layer provided on the gate insulating film;
a source electrode and a drain electrode provided in a spaced, side-by-side relationship, the source electrode and the drain electrode each being connected to the oxide semiconductor layer;
a first protective film covering the source electrode and the drain electrode, filling a gap between the source electrode and the drain electrode, and configured of a material including a silicon (Si) compound;
a second protective film covering the first protective film and configured of a material including a metal compound; and
a metal layer covering a region, over the second protective film, superposed on the gap between the source electrode and the drain electrode.

2. The thin film transistor according to claim 1,
wherein the material including the silicon compound includes one or more of a silicon oxide, a silicon nitride, and a silicon oxynitride, and
the metal compound includes one or more of an oxide, a nitride, and an oxynitride that include one or both of aluminum (Al) and titanium (Ti).

3. The thin film transistor according to claim 1,
wherein the oxide semiconductor layer includes an oxide including one or more elements of zinc (Zn), indium (In), gallium (Ga), zirconium (Zr), and tin (Sn).

4. The thin film transistor according to claim 1,
wherein the second protective film integrally and collectively covers a region superposed on the source electrode, a region superposed on the drain electrode, and the region superposed on the gap between the source electrode and the drain electrode.

5. The thin film transistor according to claim 1,
wherein the first protective film is formed by a vapor phase growth method, and
the second protective film is formed by a sputter deposition method.

6. The thin film transistor according to claim 1, further comprising a third protective film covering a region, over the oxide semiconductor layer, corresponding to the gap between the source electrode and the drain electrode.

7. The thin film transistor according to claim 1,
wherein the source electrode and the drain electrode each have a multi-layered structure in which one or more first metal films including molybdenum (Mo) and one or more second metal films including aluminum (Al) are stacked.

8. The thin film transistor according to claim 1,
wherein the metal layer has a multi-layered structure in which one or more first metal films including molybdenum (Mo) and one or more second metal films including aluminum (Al) are stacked.

9. A display unit provided with a thin film transistor and a display element configured to be driven by the thin film transistor, the thin film transistor comprising:
a gate electrode;
a gate insulating film covering the gate electrode;
an oxide semiconductor layer provided on the gate insulating film;
a source electrode and a drain electrode provided in a spaced, side-by-side relationship, the source electrode and the drain electrode each being connected to the oxide semiconductor layer;
a first protective film covering the source electrode and the drain electrode, filling a gap between the source electrode and the drain electrode, and configured of a material including a silicon (Si) compound;
a second protective film covering the first protective film and configured of a material including a metal compound; and
a metal layer covering a region, over the second protective film, superposed on the gap between the source electrode and the drain electrode.

10. An electronic apparatus provided with a display unit including a thin film transistor and a display element configured to be driven by the thin film transistor, the thin film transistor comprising:
a gate electrode;
a gate insulating film covering the gate electrode;
an oxide semiconductor layer provided on the gate insulating film;
a source electrode and a drain electrode provided in a spaced, side-by-side relationship, the source electrode and the drain electrode each being connected to the oxide semiconductor layer;
a first protective film covering the source electrode and the drain electrode, filling a gap between the source electrode and the drain electrode, and configured of a material including a silicon (Si) compound;
a second protective film covering the first protective film and configured of a material including a metal compound; and
a metal layer covering a region, over the second protective film, superposed on the gap between the source electrode and the drain electrode.

11. A method of manufacturing a thin film transistor, comprising:
forming a gate electrode on a substrate;
forming a gate insulating film covering the gate electrode;
forming an oxide semiconductor layer on the gate insulating film;
forming a source electrode and a drain electrode in a spaced, side-by-side relationship, the source electrode and the drain electrode each being connected to the oxide semiconductor layer;
forming a first protective film using a material including a silicon compound, the first protective film covering the source electrode and the drain electrode and filling a gap between the source electrode and the drain electrode;
forming a second protective film using a material including metal compound, the second protective film covering the first protective film; and
forming a metal layer covering a region, over the second protective film, superposed on the gap between the source electrode and the drain electrode.
